(19) United States
(12) Patent Application Publication
(10) Pub. No.: US 2022/0055834 A1
(43) Pub. Date: Feb. 24, 2022

(54) A STORAGE UNIT FOR SMT SUPPLIES

(71) Applicant: Mycronic AB, Taby (SE)

(72) Inventors: Peer MIETUSCH, Hoehenkirchen (DE); Goran FRANK, Ensked (SE); Nils JACOBSSON, Kungsagen (SE)

(73) Assignee: Mycronic AB, Taby (SE)

(21) Appl. No.: 17/413,735

(22) PCT Filed: Dec. 16, 2019
(86) PCT No.: PCT/EP2019/085242

§ 371 Date: Jun. 14, 2021

(30) Foreign Application Priority Data
Dec. 21, 2018 (SE) 1851655-9

(51) Int. Cl. B65G 1/04; B65G 1/06; B65G 1/133; H05K 13/08

(52) U.S. Cl. CPC B65G 1/045; H05K 13/086; B65G 1/133; B65G 1/06

(57) ABSTRACT

The present invention provides a storage unit for Surface Mount Technology (SMT) supplies, comprising a plurality of stacks having vertically stacked storage locations for SMT supplies, a terminal for inserting and receiving SMT supplies to and from said storage unit, a first collector arm for transporting SMT supplies between storage locations and said terminal, said collector arm being moveably arranged along said stacks so as to enable engagement with the vertically stacked storage locations of a stack. Further, the plurality of stacks are arranged in at least one cluster of two or more stacks in each cluster, wherein each stack of said at least one cluster is moveably arranged in relation to said collector arm so as to allow engagement of said collector arm with different stacks of the cluster upon movement of said two or more stacks in the cluster, thereby allowing said collector arm to engage storage locations of different stacks in said at least one cluster. The present invention further provides a method for operating a storage unit for SMT supplies.

### TECHNICAL FIELD

The present inventive concept relates to the field of storage of supplies for the surface mount technology (SMT) manufacturing industry.

More particularly it relates to an automatic robot storage unit, such as an automated surface mount device (SMD) warehouse.

### BACKGROUND

Surface Mount Technology (SMT) is a preferred method of automated production of electronic printed circuit boards (PCBs). So-called pick-and-place robotic machines are used in the process of placing and soldering electronic components to a printed circuit board.

As known, the electronic components, and in particular surface mount device (SMD) components, intended to be mounted on electronic boards in order to carry out precise functions, are usually wound in tapes or reels which are placed in stores or cabinets suitable for storage.

Single reels of SMD components, stored in said stores, are identified by a special code, for example of the bar code type, which contains a link to a data base with all the information relating to the type of electronic components contained in the single reels and the information relating to the location of the same reels in the store. The reels of SMD components may be managed in such stores according to semi-automatic or automatic logic, in which the operator or a control system selects the reels he/she needs by the special code and the system presents them one by one as a batch.

The SMD warehouse may form a tower unit, in which e.g. electronic components arranged in reels, or reels in palettes, are stored in vertical stacks. The pick-up and the replacement of the single reels, in the case of a fully automatic store, can take place for example by a mechanical actuator in the form of a robotic arm that pick up/replaces the reel from its containment cell or seat at a specific storage location. The reels may also be stored in trays or bins, and these trays or bins may be stored in the vertical stacks.

Thus, during operation, the component reels are inserted in the input/output port by the operator, and transported to a shelf or storage position by the robotic arm. The operator may also request a specific component reel, which is collected from its shelf position by the robotic arm and transported to the input/output port.

However, there is a need in the art for increasing the storage capacity of such SMD storage towers, without increasing the footprint, the height of the storage towers, or the cycle time to any large degree.

### SUMMARY

It is an object of the invention to at least partly overcome one or more limitations of the prior art. In particular, it is an object to provide a storage unit that allows a larger number of SMT supplies to be stored without increasing the footprint of the storage unit to a large degree.

As a first aspect of the invention, there is provided a storage unit for Surface Mount Technology (SMT) supplies, comprising
a plurality of stacks having vertically stacked storage locations for SMT supplies,
a terminal for inserting and receiving SMT supplies to and from said storage unit,
a first collector arm for transporting SMT supplies between storage locations and said terminal, said collector arm being moveably arranged along said stacks so as to enable engagement with the vertically stacked storage locations of a stack, and wherein

said plurality of stacks are arranged in at least one cluster of two or more stacks in each cluster, wherein each stack of said at least one cluster is moveably arranged in relation to said collector arm so as to allow engagement of said collector arm with different stacks of the cluster upon movement of said two or more stacks in the cluster, thereby allowing said collector arm to engage storage locations of different stacks in said at least one cluster.

The storage unit may be a surface mount device (SMD) tower. This may be an automated and flexible storage unit that is to be used near the production of electronic printed circuit boards.

The SMT supplies may comprise electronic and/or electrical components. As an example, the SMT supplies may comprise electronic components, such as resistors and capacitors. The SMT supplies may also comprise printed circuit cards and tools used in the SMT mounting process.

The storage locations may be storage locations for the SMT supplies as such, or it may be storage locations for reels comprising e.g. electronic components.

Further, the storage locations may be storage locations for trays or bins, in which the SMT supplies are stored.

As an alternative, the storage locations may be for a combination of trays and reels.

Thus, the vertical stack of storage locations may be arranged such that each location is adapted to receive and carry/hold a tray or a reel.

The terminal for inserting and receiving SMT supplies to and from said storage unit may comprise an opening with an openable door to allow access from the outside of the storage unit to the inside. The storage unit may thus comprise a housing with the stacks and the collector arm being arranged within the housing and the terminal arranged for allowing access from the outside of the housing to the inside. The terminal may further comprise a scanner, camera and/or sensors for determining and confirming that the correct component of the SMT supplies has been retrieved by the collector arm and what component of the SMT supplies is to be stored within the storage unit.

The collector arm may be an actuator, such as a robotic arm. The collector arm is arranged to be guided or moved in the vertical direction. Thus, the collector arm may be moveably arranged around a shaft extending in the vertical direction. It is to be understood that the storage unit may comprise more than one collector arm, such as at least two or at least four, collector arms.

The collector arm may be rotatably arranged around a vertical axis. Upon rotation around this axis, the collector arm may move between terminal and the SMT supplies in the storage unit. Thus, in embodiments of the first aspect, the first collector arm is rotatably arranged around a vertical axis (Z) such that the collector arm is configured to switch between engaging said terminal and the at least one cluster upon rotational movement around the vertical axis (Z).

The storage unit may further comprise a control unit configured to carry out a method of operating a storage unit according to embodiments disclosed herein. For this purpose, the control unit may comprise a processing unit, such as a central processing unit, which is configured to execute computer code instructions which for instance may be stored on a memory. The processing unit may be communicatively coupled to the collector arm. Such a processing unit may thus be configured for receiving, e.g. from an operator (e.g. pushing a button) or from a memory or processor in an external communications network to which said storage unit is connected, at least one of input data, a parameter or SMT job related information representing a storage position within the storage unit. The processing unit may be configured for receiving input data via an input/output interface.

Hence, the storage unit may further comprise an input/output interface for receiving and/or displaying information on which component of the SMT supplies that is to be retrieved or stored.

Furthermore, the collector arm may be configured to present the collected component of the SMT supplies of the storage position at, or close to, the terminal of the storage unit based on such control data from said processor.

The stacks of the storage unit are arranged in at least one cluster of two or more stacks in each cluster. Each stack in the cluster is moveably arranged in relation to the collector arm. This allows the collector arm to engage the different stacks of a cluster upon movement of the stacks in a cluster. Thus, the stacks of a cluster can be moved in relation to the collector arm even when the collector arm is still and does not move.

The storage unit may comprise one or several clusters in which the stacks are moveably arranged in relation to the collector arm and also stacks that are stationary in relation to the collector arm. As an example, the storage unit may comprise a single cluster of in which the stacks are moveably arranged in relation to the collector arm and at least one, such as at least three, stationary stacks.

The storage unit may comprise a motor, such as a stepper motor or similar drive, arranged for moving the stacks of a cluster in relation to the collector arm.

The first aspect of the invention is based on the insight that arranging the stacks in at least one cluster and making the stacks in the cluster moveable in relation to the collector arm, the storage capacity of the storage unit may be increased without increasing the access time for the collector arm. Thus, while the collector arm is presenting a first collected component of the SMT supplies at the terminal that was retrieved from a storage location while the stacks were in a first position, the storage unit allows for simultaneously moving the stacks to a second position so as to allow the collector arm to directly engage a second storage location after presenting the first collected component of the SMT supplies.

Furthermore, having stacks arranged in clusters and arranging them to be moveable in relation to the collector arm, the floor space required for the storage unit increases to a minor degree compared to the increase in storage capacity.

As compared to a solution having solely stationary stacks of vertically stacked storage locations, the storage unit of the present invention, with only a small increase in floor space, may double the capacity of storing e.g. reels of electronic components without increasing the access time.

In embodiments of the first aspect, the storage unit is comprising at least two, such as at least three, such as at least five, clusters of two or more stacks in each cluster.

However, the storage unit may also comprise more than eight, such as more than ten clusters.

In embodiments of the first aspect, each cluster comprises at least three, such as at least five, stacks having vertically stacked storage locations.

Consequently, the storage unit may comprise at least five clusters wherein each cluster comprises at least three, such as at least five, stacks having vertically stacked storage locations.

In embodiments of the first aspect, said clusters are spaced around a vertical axis (Z) and said first collector arm is moveably arranged along said vertical axis (Z) and rotatably arranged around vertical axis (Z) so as to enable engagement with the vertically stacked storage locations of a stack at a radial position P from vertical axis (Z).

Consequently, the first collector may be arranged to engage the different clusters based on the rotational movement and engage different storage locations of a stack by a vertical movement along vertical axis (Z). All engagements with a stack may thus be at a radial position P from the vertical axis (Z). By moving the stacks in a cluster, the stack being at radial position P may be shifted for another stack in the cluster, thereby allowing the collector arm to engage different stacks of a cluster.

The first collector arm may be rotatably arranged around a static shaft.

In embodiments of the first aspect, the first collector arm is moveably arranged in the horizontal and vertical direction.

Furthermore, the first collector arm may be moveably in the horizontal and vertical direction and also be rotatably arranged around a vertical axis (Z). As an example, the collector arm may be moveably arranged along a vertical shaft and rotatably arranged around the shaft, wherein the shaft is arranged along a vertical extends along vertical axis (Z). this shaft may in turn be moveably arranged in the horizontal direction.

As an example, at least one cluster of stacks may be a rotatable carousel of two or more stacks. Each carousel may thus be rotatable around an individual carousel axis (Zᵢ) that is parallel to rotational axis (Z) and arranged to allow different stacks of a carousel to reach the radial access position P upon rotation of said carousel around carousel axis (Zᵢ).

The rotation of the stacks in a cluster may be performed by a stepping motor such that each step of the motor switches the stack being at radial position P is shifted for another stack. Thus, the rotatable carousels may be rotatable in discrete steps corresponding to the number of stacks in the carousel. Upon rotation of the carousel one step, the stack in the carousel being at radial access position P rotates away and an adjacent stack rotates into radial access position P.

However, the rotatable carousel may also be continuously rotatable around its around carousel axis Zᵢ.

Moreover, the rotatable carousels may be spaced concentrically around vertical axis (Z).

As a further example, the individual carousel axes (Zᵢ) may be arranged on a circle line around vertical axis (Z).

The storage unit may comprise at least three, such as at least five, rotatable carousels of two or more stacks in each carousel. Each carousel may comprise at least three, such as at least five, stacks having vertically stacked storage locations.

As a further example, the storage unit may comprise at least five carousels, each carousel comprising at least five stacks having vertically stacked storage locations.

In embodiments of the first aspect of the invention, the stacks of at least one cluster are arranged in a moveable loop such that a movement of the stacks in the loop allows said first collector arm to engage storage locations of different stacks in said moveable loop.

A moveable loop may be in the form of a paternoster loop. The moveable loop may have different discrete positions for the stacks and one of those positions may be an engagement position for the collector arm. Movement of the stacks within the loop thus may thus allow different stacks in the cluster to reach the engagement position. The moveable loop may be arranged to move stepwise, e.g. by the use of a stepping motor or similar drive, and upon movement one step the stack at the engagement position may be switched for another stack.

In embodiments of the first aspect of the invention, at least one cluster comprises X number of static stack positions occupied by less or equal to (X−1) stacks, and wherein a rearrangement of said (X−1) stacks in said stack positions allows said first collector arm to engage storage locations of different stacks in said cluster.

Thus, a cluster may comprise stack positions, e.g. arranged in a horizontal array pattern. One, or at least one, of the X number of positions may be an engagement position for a collector arm. A movement corresponding to a rearrangement or redistribution of the stacks among the stack positions may allow different stacks in the cluster to reach the engagement position.

In embodiments of the first aspect of the invention, the clusters are moveably arranged in relation to said first collector arm.

Thus, the clusters themselves may be moveably arranged in relation to the collector arm. The stacks of a cluster may thus be arranged on a base plate that in itself is moveable in the horizontal plane. The stacks may be fixedly arranged on such a base plate or moveably arranged on the base plate. As an example, the base plate and the stacks may form a rotatable carousel as discussed herein above, and the base plate itself may be moveably arranged in the horizontal plane. The base plate may be a vehicle. Thus, the clusters may be arranged onto individual vehicles capable of moving freely in relation to said first collector arm. Such vehicles may be Automated Guided Vehicles (AGV:s).

In embodiments of the first aspect of the invention, the SMT supplies are stored in component reels, and said reels are arranged in the vertically stacked storage locations of said stacks.

Thus, as discussed above, the SMT supplies may comprise electronic components that are stored in component reels. However, the SMT supplies may also be stored in bins or trays, and each storage location may comprise one such bin or tray.

Further, in embodiments of the first aspect of the invention, at least one cluster forms a dockable unit that may be loaded and unloaded in the storage unit.

This allows for the storage unit to be loaded with different types of clusters depending on the specific SMT application. Thus, a single storage unit may be used for several applications by simply docking desired clusters into the storage unit.

The present invention further allows for large storage units having more than one terminal and collector arm. Consequently, in embodiments of the first aspect of the invention, the storage unit is further comprising a second terminal for inserting and receiving SMT supplies to and from the unit, and a second collector arm arranged for transporting SMT supplies between storage locations and said second terminal, said second collector arm being moveably arranged in the vertical direction along said stacks so as to enable engagement with the vertically stacked storage locations of a stack.

The storage unit may thus form an integrated Surface Mount Device (SMD) warehouse cluster comprising a plurality of collector arms and terminals, and SMT supplies may be stored, retrieved and redistributed among the stacks of the SMD warehouse cluster.

Thus, the clusters of stacks of the storage unit may be shared among all collector arms, or some may be assigned to a single collector arm only. As an example, the clusters of stacks are arranged into at least a first group of clusters, which is arranged for allowing engagement with only the first collector arm, at least one shared cluster, which is arranged for allowing the different stacks of the shared cluster to engage with both collector arms simultaneously, and at least a second group of clusters, which is arranged for allowing engagement with only the second collector arm.

As an example, the shared cluster may be a single cluster of stacks that is shared between the two collector arms.

Having shared clusters is advantageous in that it allows for redistribution of SMT supplies within the storage unit, e.g. redistribution from stacks that are a few number of free, unoccupied storage locations to stacks that have a large number of free, unoccupied storage locations.

Further, as an example, the stacks of at least one shared cluster are arranged in a moveable loop such that a movement of the stacks in the loop allows said collector arms to engage storage locations of different stacks in said moveable loop.

Thus, the shared cluster or clusters are advantageously arranged in a moveable loop as discussed herein above. The moveable loop may comprise at least five, such as at least seven, stacks. A shared cluster in the form a moveable loop may allow for a desired space between two collector arms

It is to be understood that the storage unit may comprise more than two collector arms and terminals, such as at least three, such as at least five collector arms and terminals.

The storage unit may further comprise an absorption unit that is arranged to feed in dry air to produce a controlled storage atmosphere in the storage unit.

The storage unit of the first aspect of the invention may be used for storing other products than SMT supplies. As an example, the storage unit may be for storing articles of medicine, such as jars or packages comprising medicines. Thus, as an alternative aspect of the first aspect of the invention, there is provided
a storage unit for products, comprising
a plurality of stacks having vertically stacked storage locations for products,
a terminal for inserting and receiving products to and from said storage unit,
a first collector arm for transporting products between storage locations and said terminal, said collector arm being moveably arranged along said stacks so as to enable engagement with the vertically stacked storage locations of a stack, and wherein

said plurality of stacks are arranged in at least one cluster of two or more stacks in each cluster, wherein each stack of said at least one cluster is moveably arranged in relation to said collector arm so as to allow engagement of said collector arm with different stacks of the cluster upon movement of said two or more stacks in the cluster, thereby allowing said collector arm to engage storage locations of different stacks in said at least one cluster.

As a second aspect of the invention, there is provided a method for operating a storage unit for SMT supplies according to the first aspect. The method is comprising the steps of
a1) receiving a first input data representing a first target location of a target stack for the collector arm;
b1) moving at least one stack of a cluster to enable engagement with the vertically stacked storage locations of the target stack by said collector arm;
c1) moving said collector arm from the terminal into engagement with said first target location of said target stack and collecting or storing a component of the SMT supplies at said first target location; and
d1) moving the collector arm back to the terminal.

This aspect may generally present the same or corresponding advantages as the former aspect. The method of the second aspect of the invention may be a step of a Surface Mount Technology (SMT) production of electronic printed circuit boards (PCBs).

The method may be performed by a control unit, which may be an integrated part of the storage unit or a stand-alone part. Such a control unit may thus be configured to carry out a method of operating a storage unit according to embodiments disclosed herein.

Further, the step b1) of moving at least one stack of a cluster may also comprise redistributing a component of the SMT supplies from a storage location to the actual target location.

Step b1) of moving the at least one stack may be performed before step c1) of moving the collector arm or simultaneously as step c1).

Further, the method may comprise repeating the sequence of steps a1)-d1) any number of times. For example, step a1) and/or b1) may be performed simultaneously as step d1) is performed in a previous sequence. Consequently, in embodiments of the second aspect of the invention, the method is further comprising the steps of
a2) receiving a second input data representing a second target location of a target stack for the collector arm;
b2) moving at least one stack of a cluster to enable engagement with the vertically stacked storage locations of the target stack by said collector arm;
c2) moving said collector arm from the terminal into engagement with said second target location of said target stack and collecting or storing a component of the SMT supplies at said second target location; and
d2) moving the collector arm back to the terminal;
wherein at least one of steps a2) and b2) are performed simultaneously as any one of steps c1) or d1).

Furthermore, the method may comprise the step of receiving a component of the SMT supplies to be stored in said storage unit by a collector arm at a terminal for inserting and receiving SMT supplies and step c) may further comprise storing said component of the SMT supplies to be stored at said target location of said target stack.

### BRIEF DESCRIPTION OF THE DRAWINGS

The above, as well as additional objects, features and advantages of the present inventive concept, will be better understood through the following illustrative and non-limiting detailed description, with reference to the appended drawings. In the drawings like reference numerals will be used for like elements unless stated otherwise.

FIG. 1 is an illustration of a storage unit of the present disclosure.

FIG. 2a is a schematic perspective view of the inside of a storage unit.

FIG. 2b is a schematic top view of the inside of the storage unit shown in FIG. 2a.

FIG. 3. is a schematic top view of an embodiment of a storage unit in which the clusters are in the form of rotatable carousels.

FIG. 4 is a schematic top view of an embodiment of a storage unit in which the stacks of a cluster are moveable in an array of stack positions.

FIG. 5 is a schematic top view of an embodiment of a storage unit in which the clusters are in the form of a moveable loop of stacks.

FIGS. 6a and 6b are a schematic top views of embodiments of storage units in which some clusters are shared among two collector arms.

FIG. 7a is a schematic perspective view of a cluster arranged on an Automated Guided Vehicle (AGV).

FIG. 7b. is a schematic top view of an embodiment of a storage unit comprising clusters on Automated Guided Vehicles (AGVs).

FIG. 8 is a schematic flow chart of a method of operating a storage unit of the present disclosure.

FIGS. 9a and 9b are schematic drawing of a bin and a tape reel that may be stored in the storage unit.

FIG. 10 is a further schematic drawing of a bin that may be stored in the storage locations of the storage unit.

### DETAILED DESCRIPTION

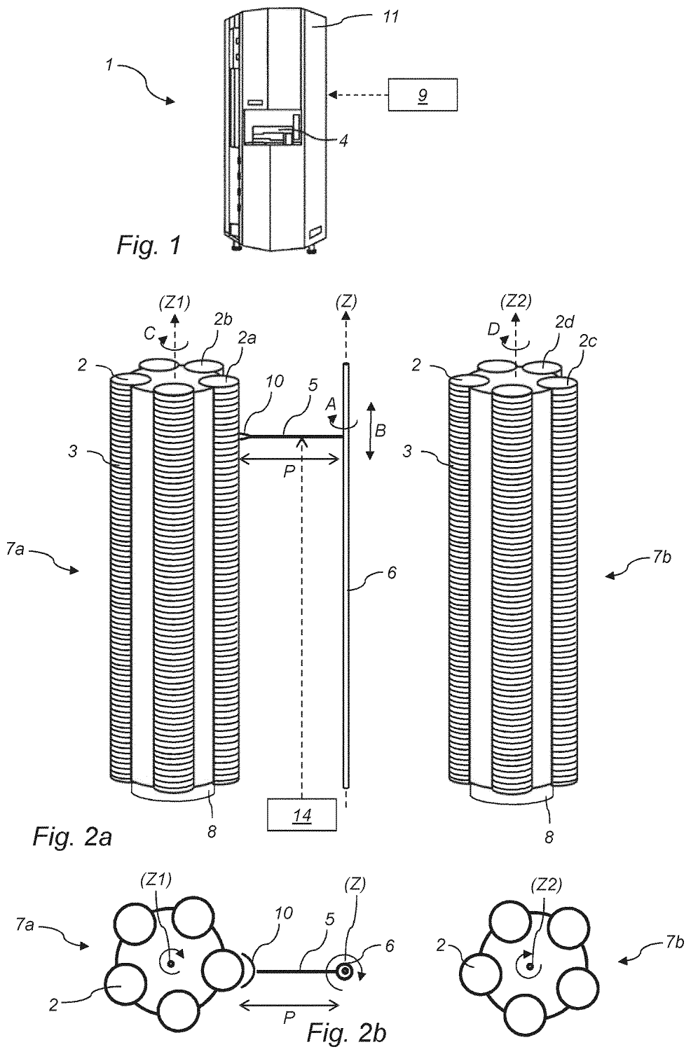

FIG. 1 shows a side view storage unit 1 of the present disclosure in the form of an automated surface mount device (SMD) tower. The storage unit 1 comprises a frame 11 housing a plurality of stacks 2 having vertically stacked storage locations 3 for SMT supplies. A terminal 4, arranged on a side wall of the frame 3, is used as an input and output port for SMT supplies into the warehouse. The storage unit 1 further comprises an input/output device 9 that is adapted to receive user indication data and to send the user indication data to a control unit 14, which uses the data to control a collector arm 5 within the frame 11 for transporting components between storage locations and the terminal 4.

The footprint of the storage unit may be less than 4 m², such as less than 2 m².

The input/output device may be integrated in the storage unit, e.g. as a part of the frame 11, or it may be an external device configured to communicate with the control unit 14. The user indication data may be received from an operator or retrieved as information from and SMT information database.

FIG. 2a is a schematic view of the inside of the storage unit 1 whereas FIG. 2b is a top view of the inside of the storage unit 1 as shown in FIG. 2a. FIGS. 2a and 2b show a plurality of stacks 2 comprising vertically stacked storage locations for SMT supplies and the collector arm 5 for transporting components between storage locations 3 and the terminal 4.

The stacks 2 having vertically stacked storage locations 3 may extend to the top of the storage unit 1. A single stack 2 may have more than 50 storage locations, such as more than 100 storage locations, such as more than 500 storage locations, that are stacked on top of each other. The storage locations 3 may be for store component reels, such as store component tape reels being between 5 and 50 mm thick with a diameter of between 80 mm to 400 mm. The reels may be stored directly in the storage locations 3 or may be stored in bins or trays at the storage locations 3.

The stacks 2 are in this embodiment arranged in two clusters 7a, 7b of five stacks in each cluster. Each cluster 7a, 7b comprises a stationary base plate 8 onto which the stacks are rotatably arranged around a vertical rotational axis Zi. Thus, the stacks 2 of cluster 7a are rotatably arranged around vertical axis Z1, as illustrated by arrow “C” in FIG. 1, whereas the stacks 2 of cluster 7b are rotatably arranged around vertical axis Z2, as illustrated by arrow “D” in FIG. 1. Thus, the stationary base plate 8 rotatably supports the stacks of a cluster.

The clusters 7a,b are spaced around a vertical axis (Z) and the collector arm 5 is moveably arranged in the vertical direction along stacks and along axis Z, as illustrated by arrow “A”. The collector arm 5 may for example be moveably arranged in the vertical direction along a shaft 6 that extends in the vertical direction Z. This enables engagement with the vertically stacked storage locations of a stack 2. The collector arm 5 may be a robotic arm equipped with engagement means 10 for gripping and releasing e.g. a reel or a bin at a storage location 3. The collector arm may thus function as an actuator.

In this example, the collector arm 5 is also rotatably arranged around shaft 6, and thus rotatably arranged around vertical axis (Z), as illustrated by arrow “B” in FIG. 1. This enables engagement with the vertically stacked storage locations of a stack at a radial position P from vertical axis (Z).

Due to the rotationally supported stacks 2, each cluster 7a,b is moveably arranged in relation to the collector arm 5 so as to allow engagement collector arm with different stacks 2 of a cluster 7a,b, thereby allowing the collector arm 5 to engage vertically stacked storage locations 3 of different stacks 2 in the cluster 7a,b. For example, this allows for stack 2a in cluster 7a to be rotated into a position in which the collector arm 5 can engage and access the storage locations, and then be rotated away from the collector arm 5 to allow e.g. stack 2b to be accessed instead. Further, stacks 2c or 2d from cluster 7b may be rotated into an engagement position at radial distance P from vertical axis (Z) meanwhile the collector arm 5 engages the storage locations from cluster 7a. In this way, the storage capacity of the storage unit is increased as compared to a storage unit having static stacks, without increasing the access or picking time.

Consequently, in this embodiment, the clusters for rotatable carousels for the stacks, i.e. the clusters are able to rotate and thereby allow different individual stacks of a cluster to reach an engagement position for the collector arm at radial position P from rotational axis (Z) by a rotational movement. The rotational movement may be performed by a stepping motor or similar drive, and with each step of the motor the stacks may rotate one step clockwise or counter-clockwise, thereby allowing an adjacent stack to reach the engagement position at radial position P.

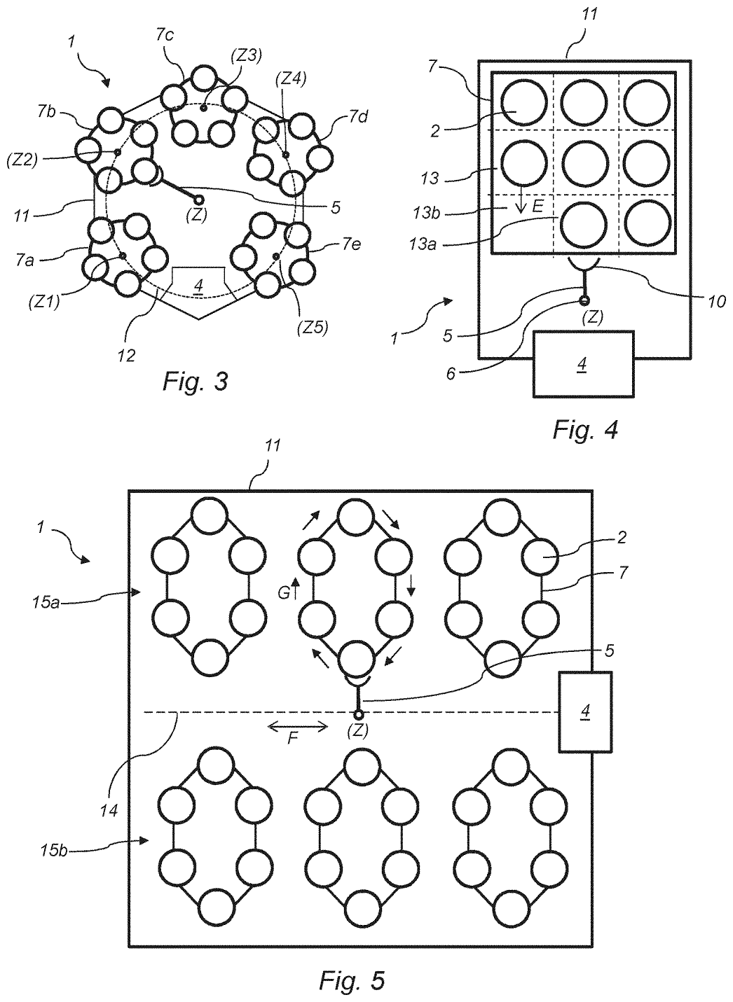

FIG. 3 shows a top view of a schematic embodiment of a storage unit 1 of the present disclosure. The storage unit 1 comprises five clusters 7a-e arranged in a frame 11. Each cluster forms a rotatable carousel of five different stacks 2 with storage locations for SMT supplies in each carousel. As in the embodiment disclosed in FIGS. 2a and 2b, the stacks are rotatably arranged around individual carousel axes Z1-Z5. The clusters are spaced around the central vertical rotational axis (Z) of the collector arm 5 such that the individual carousel axes Z1-Z5 are arranged on a circle line 12 around vertical axis Z. The individual carousels are arranged to rotate independently from the other carousels and are arranged at a distance from collector arm so that the collector arm 5 is able to engage a storage location of a stack with engagement means 10 at a radial distance P from rotational axis Z, and thus deliver a component of the SMT supplies to terminal 4 or store a received component of the SMT supplies from terminal 4 in any of the stacks 2.

FIG. 4 shows a top view of another illustrative embodiment of a storage unit 1 of the present disclosure. The cluster 7 of stacks 2 comprises in this embodiment nine of static stack positions 13 occupied by eight stacks 2, all arranged within frame 11. The static stack positions 13 are in this embodiment arranged as a 3×3 array. Thus, one of the positions 13 is thus always an empty position 13b. As described in relation to the previous embodiments above, the storage unit has a rotatable collector arm 5 with engagement means 10 arranged to rotate around shaft 6 that extends in the vertical direction, thereby allowing collector arm 5 to rotate around vertical axis (Z). The collector arm 5 may also move in the vertical direction along shaft 6 to access different storage locations of a stack. A collected component of the SMT supplies may then be presented at terminal 4. In this embodiment, one of the static stack positions is an engagement position 13a, in which the collector arm may access the stack at the engagement position by engagement means 10. Further, the stacks 2 are moveably arranged in the horizontal plane among the array of static stack positions 13. This allows a neighbouring stack to move in the horizontal direction into the empty position 13b, as illustrated by arrow E, thereby creating another empty position. Thus, the stacks 2 may be rearranged in the horizontal plane to move different stack into the engagement position 13a, thereby allowing the collector arm 5 to engage storage locations of different stacks 2 in the cluster 7. The example in FIG. 4 shows a single cluster 7, but it is to be understood that the storage unit 1 may comprise several clusters 7 comprising X number of static stack positions occupied by less or equal to (X−1) stacks, arranged such that a rearrangement of the (X−1) stacks allows a collector arm to engage storage locations of different stacks of a cluster.

FIG. 5 shows a top view of another illustrative embodiment of a storage unit 1 of the present disclosure. In this example, the individual clusters 7 are arranged as a moveable loop such that a movement of the stacks 2 in the loop, as illustrated by arrows G in FIG. 5, allows the collector arm 5 to engage storage locations of different stacks in a moveable loop. The movement of the stacks 2 in a loop may be performed by a stepping motor or similar drive (not shown), and the stacks may be arranged to move in both directions, such as both clockwise and counter-clockwise. As discussed in relation to the previous examples, there is a terminal 4 for inserting and receiving SMT supplies to and from the storage unit 1. The clusters 7 arranged as moveable loops forms two rows 15a, 15b of clusters, and the collector arm 5 is further arranged to move in the horizontal plane along line 14 between the two rows 15a, 15b, as illustrated by arrow F in FIG. 5. Line 14 thus extend from the terminal 4 and to the end of the two rows 15a, 15b. Further, as in the previous examples, the collector arm 5 may further move in the vertical direction along axis (Z) to engage different storage locations of a stack, and the collector arm is also rotatable around axis (Z) in order to allow for engagement with both rows 15a, 15b of clusters. In FIG. 5, all clusters 7 of both rows 15a, 15b are arranged as moveable loops. However, it is to be understood that some clusters 7 in the loops could be arranged as rotatable carousels, as illustrated in FIGS. 2 and 3, and there could also be just a single, static stack at one or several cluster positions.

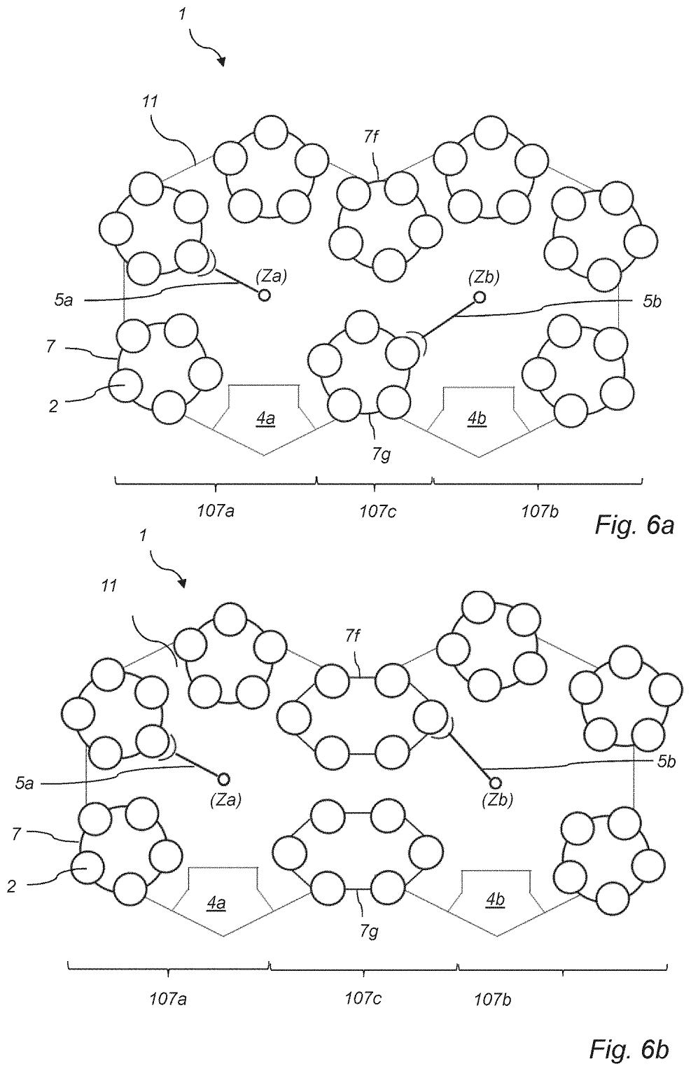

FIGS. 6a and 6b show top views of further illustrative embodiments of a storage unit 1 of the present disclosure. The storage unit 1 of FIG. 6a is similar to the storage unit as described in relation to FIG. 3 above. However, in this example, the storage unit 1 is extended to comprise a second terminal 4b and a second collector arm 5b. Thus, in the embodiment as shown in FIG. 6a, the storage unit comprises a first collector arm 5a, which is moveable along and rotatable around a first vertical axis Za, as well as a second collector arm 5b, which is moveable along and rotatable around a second vertical axis Zb. Thus, the first collector arm 5a serves the first terminal 4a whereas the second collector arm 5b serves the second terminal 4b.

The clusters 7 of the storage unit are arranged into a first group of clusters 107a, which is arranged for allowing engagement with only the first collector arm 5a and a second group of clusters 107b, which is arranged for allowing engagement with only the second collector arm 5b. There is also a shared group of clusters 107c, consisting of cluster 7f and 7g, which is arranged for allowing different stacks of the shared cluster to engage with both collector arms 5a, 5b simultaneously.

The second vertical axis Zb is thus arranged radially outside the rotatable carousels of the first group of clusters 107a as seen from vertical axis Za and at a distance from at least one rotatable carousel of the shared cluster 107c such that the storage locations of the stacks of the at least one rotatable carousels of the shared cluster 107c may be engaged by the second collector arm 5b. Thus, the rotatable carrousels of the second group of clusters 107b are rotatable so as to allow different stacks of a carousel to reach a radial access position upon rotation of the carousel, thereby allowing the second collector arm 5b to access storage locations of different stacks of the carousels of the second group 107c.

By the use of the two collector arms 5a and 5b, SMT supplies may efficiently be redistributed among all the clusters, such as from the first group of clusters 107a to the second group of clusters 107b via the shared group of clusters 107c.

The embodiment as shown in FIG. 6b is identical to the embodiment of FIG. 6b, except that the clusters 7f and 7g of the shared group of clusters 107c are clusters in which the stacks 2 are arranged in a moveable loop. This may be advantageous in that it allows the first 5a and second 5b collector arms to be spaced a larger distance apart.

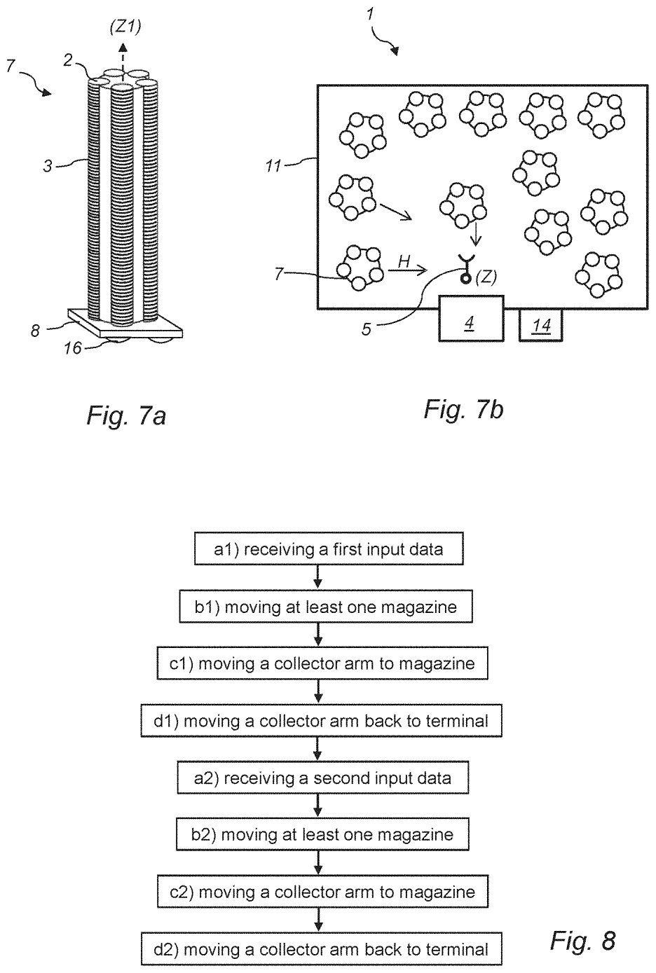

FIGS. 7a and 7b show another illustrative embodiment of a storage unit 1 of the present disclosure. FIG. 7a is a side view of a cluster 7 in the form of a rotatable carousel as described in relation to FIGS. 2a and 2b above. However, the base plate 8 is in this example in the form of a vehicle capable of moving freely in the horizontal direction within the storage unit 1 and to the collector arm 5. This is illustrated with arrows H in FIG. 7b, which is an illustrative top view of a storage unit 1 comprising clusters arranged on vehicles. Thus, FIGS. 7a and 7b illustrate an example in which the clusters themselves are moveable in relation to the collector arm 5. The base plate or vehicle 8 may thus be equipped with wheels 16 and is in this example an automated guided vehicle (AGV).

The cluster 7 is not required to be moveable or rotatable in relative the base plate 8, but the storage unit 1 may rely on the motions of the vehicle to allow for the different stacks 2 of the cluster to reach a collector arm 5.

As seen in FIG. 7b, the storage unit 1 may within its frame comprise a plurality of clusters 7 on individually vehicles arranged for moving freely in the horizontal plane within the frame 11. The clusters 7 may then be randomly distributed within the frame 11, and may thus be distributed within the frame 11 at a high density.

Thus, during use, the operator may place a component of the SMT supplies at the terminal 4, at which the component is collected by the collector arm 5. A control unit 14 of the storage unit 1 may then call an individual AGV, which then travels to the collector arm 5 and receives the electric component. The collector arm 5 is also in this embodiment arranged to move in the vertical direction along vertical axis (Z) and also rotatable around axis Z.

In analogy, when an operator requests a specific electric component, the control unit 14 may call the corresponding AGV which travels to the collector arm 5 for providing the requested electric component. The collector arm may then engage the target storage location and present the requested electric component at the terminal 4.

A terminal 4 and a collector arm 5 may in the embodiment shown in FIG. 7b form a central unit and the moveable clusters 7 may be independent on such a central unit. Thus, they do not have to be located within the same frame 11. This may make the storage unit 1 more flexible. A cluster may further have a Unique Identity Code ID which could be recognized by the control unit 14. This may confirm that the correct cluster is docked with the correct collector arm 5 and terminal 4.

As discussed above, the storage unit 1 may further comprise an input/output device 9 that is adapted to receive user indication data and to send the user indication data to a control unit 14. The control unit 14 may thus be configured to carry out a method for controlling one or several electrical motors for moving and rotating a collector arm and steppermotors or similar drives for moving the clusters.

For this purpose, the control unit 14 may comprise a processing unit, such as a central processing unit, which is configured to execute computer code instructions which for instance may be stored on a memory. The memory may thus form a (non-transitory) computer-readable medium for storing such computer code instructions. The processing unit may alternatively be in the form of a hardware component, such as an application specific integrated circuit, a field-programmable gate array or the like.

The control unit 14 may be connected to motors for controlling the collector arms and to stepping motors for controlling the movements of the clusters. The control unit 14 may therefore comprise a communication interface, such as a transmitter/receiver, via which it may receive data from the various electrical motors. The received data may for instance include data on position of the collector arm and the position of the stacks in the clusters. The transmitted data may for instance include a control signal for controlling the various electrical motors.

Consequently, the control unit 14 may be configured for carrying out a method for retrieving and presenting objects in a storage unit of the present disclosure. The method is illustrated in FIG. 8 and comprises the steps of

a1) receiving a first input data representing a first target location of a target stack for the collector arm;

b1) moving at least one stack of a cluster to enable engagement with the vertically stacked storage locations of the target stack by said collector arm;

c1) moving said collector arm from the terminal into engagement with said first target location of said target stack and collecting or storing a component of the SMT supplies at said first target location; and

d1) moving the collector arm back to the terminal.

The method may further comprise the steps of

a2) receiving a second input data representing a second target location of a target stack for the collector arm;

b2) moving at least one stack of a cluster to enable engagement with the vertically stacked storage locations of the target stack by said collector arm;

c2) moving said collector arm from the terminal into engagement with said second target location of said target stack and collecting or storing a component of the SMT supplies at said second target location; and

d2) moving the collector arm back to the terminal.

The stacks of another cluster may be moved into a desired position while the collector arm 5 picks components or deliver components to the terminal 4. Consequently at least one of steps a2) and b2) may performed simultaneously as any one of steps c1) or d1). This means that the second input data and/or moving the stacks based on this data may be performed during the step of moving the collector arm to the terminal based on instructions in the first input data.

As discussed above, the storage unit may be an automated Surface Mount Device (SMD) warehouse adapted to obtain information related to upcoming SMT jobs. The method may thus comprise receiving at least one of input data and a parameter representing a position or storage location within said automated Surface Mount Device (SMD) warehouse, retrieving a bin, by the use of a collector arm, loaded with a plurality of bin load units, from said position within said automated SMD warehouse at least partly based on said at least one of input data and/or a parameter representing said position within said automated Surface Mount Device (SMD) warehouse and presenting, by the use of a collector arm, the retrieved bin at, or close to an output port of the automated Surface Mount Device (SMD) warehouse. Thus, in the technology disclosed, the collector arm 5, e.g. a mechanical hand or robot arm, is adapted to be controlled by the processor of the control unit 14 to receive e.g. a bin at a terminal of an automated Surface Mount Device (SMD) warehouse. The collector arm may further be adapted to store the bin at a storage location or position within the automated Surface Mount Device (SMD) warehouse and the control unit may be configured to store the position and alternatively a bin ID, a pallet ID, a component tape reel ID or an SMT feeder ID in a memory.

In the technology disclosed, the storage unit 1 may itself have a large physical volume and may further be configured to store bins with a large physical volume.

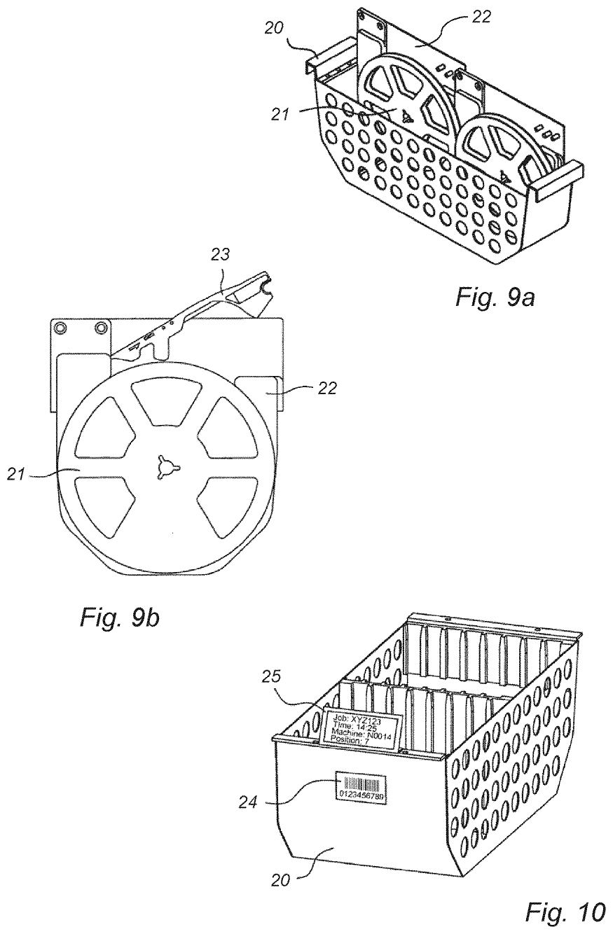

FIG. 9a shows an example of a bin 20. These bins 20 may be used for storing reels 21 of electronic components stored in bin load units 22 of the bin 20. Thus, the vertically stacked storage locations 3 of a storage unit 1 may be for storing bins 20.

Bin is in this document to be understood as a basket, trolley or accumulator adapted to comprise packet units of component tape reels and optional SMT feeder/tape guide, pallets or any component handled by an SMT pick and place machine in one or more slots or compartments and adapted with an attachment arrangement allowing storage in a position in an automated Surface Mount Device (SMD) warehouse and an SMT pick and place machine, as would be understood by a person skilled in the art.

The bins 20 may be configured with wheels to form a trolley, e.g. where each bin/trolley is adapted to hold multiple bin load units 22 or even adapted to hold a plurality of baskets each with compartments or slots adapted to hold multiple bin load units 22. The bins or trolleys, which in this aspect of the technology disclosed are adapted to be stored in an automated SMD warehouse, may further be configured to hold a plurality of SMT component tape reels 21, with or without a driving/feeding mechanism, where the bin/trolley is further be arranged to be positioned in an SMT pick and place machine (not shown) for immediate operation. The bins or trolleys 20 may further be configured to feed the components of the component tape reels 21 directly to the pick-up positions associated with a SMT pick and place machine, where said SMT component feeders or tape guides may have a built-in tape advancing mechanism or utilize a tape advancing mechanism of the pick and place machine or the magazine (tape guide), e.g. a feeding wheel or a protrusion utilizing an internal or external drive such as a linear motor.

FIG. 9b further shows a bin load unit 22 in the form of a pallet comprising component tape reel 21 and a SMT component feeder 23, which may be stored in the bins 20. The component tape reel 21 may comprise series of pockets of appropriate depth in the tape, holding one electronical component in each pocket.

The SMT component feeder 23 is adapted to feed or advance a pocket tape from the component tape reel 21 and to remove a thin cover tape closing the pockets. The SMT component feeder 23 may have a built-in tape advancing mechanism or utilize a tape advancing mechanism of a SMT pick and place machine (this type of passive component feeder without a built-in tape advancing mechanism or other driving/feeding means/mechanisms that utilizes a tape advancing mechanism of the pick-and-place machine for guiding/feeding the component tape to its pick-up position in the pick-and-place machine is typically referred to as a “tape guide”). The SMT feeder 23 may be arranged to utilize e.g. a feeding wheel or a protrusion utilizing an internal or external drive such as a linear motor or similar drive, in the pick-and-place machine or magazine protrudes through the tape guide into contact with the pre-threaded tape. The SMT component feeder 23, or tape guide, might be adapted to comprise an SMT feeder ID that might be stored and associated to other identities in said SMT information database, e.g. associated to a component tape reel ID. The technology disclosed in this document also enables that the SMT component feeder 23 or tape guide also may be adapted to comprise an SMT feeder ID that might be stored and associated to identities of other types of units such as bin IDs or pallet IDs used in the SMT process, and where the bin IDs or pallet IDs also may be stored as IDs in an SMT information database.

Furthermore, as seen in FIG. 10, the bin 20 may comprise an alphanumerical display 25 with an integrated alphanumerical display controller and a bin identity tag 24, e.g. attached to the bins forward facing surface such that the surface is facing an operator when handling the bin. The display data on identity tag 24 may comprise a bin ID, wherein said bin ID is presented as a bar code, QR code or the like.

The alphanumerical display controller of the alphanumerical display 25 can optionally recognize and register bin load units 22 placed in the bin 21, e.g. by scanning barcodes or RFID tags attached to the bin load units. The scanning may be performed manually by a handheld barcode tag/RFID tag scanner or by a barcode tag/RFID tag scanner integrated in the bin 20. Alternatively, the alphanumerical display controller is configured to communicate data, e.g. identities of recognize and register bin load units 22, via a communications network to an SMT information database, e.g. such that information on the content of the bin 20 is available in the SMT information database. Alternatively, the bin 20 is further configured with wheels to form a trolley such that the bin 20 can be retrieved manually or automatically from storage unit 1 and positioned in an SMT pick and place machine 91 for immediate operation.

In the above the inventive concept has mainly been described with reference to a limited number of examples. However, as is readily appreciated by a person skilled in the art, other examples than the ones disclosed above are equally possible within the scope of the inventive concept, as defined by the appended claims.

1. A storage unit for Surface Mount Technology (SMT) supplies, comprising
a plurality of stacks having vertically stacked storage locations for SMT supplies,
a terminal for inserting and receiving SMT supplies to and from said storage unit,
a first collector arm for transporting SMT supplies between storage locations and said terminal, said collector arm being moveably arranged along said stacks so as to enable engagement with the vertically stacked storage locations of a stack, and wherein
said plurality of stacks are arranged in at least one cluster of two or more stacks in each cluster, wherein each stack of said at least one cluster is moveably arranged in relation to said collector arm so as to allow engagement of said collector arm with different stacks of the cluster upon movement of said two or more stacks in the cluster, thereby allowing said collector arm to engage storage locations of different stacks in said at least one cluster.

2. A storage unit according to claim 1, wherein the first collector arm is rotatably arranged around a vertical axis such that said collector arm is configured to switch between engaging said terminal and said at least one cluster upon rotational movement around said vertical axis.

3. A storage unit according to claim 1, wherein said clusters are spaced around a vertical axis and further wherein said first collector arm is moveably arranged along said vertical axis and rotatably arranged around said vertical axis so as to enable engagement with the vertically stacked storage locations of a stack at a radial position P from said vertical axis.

4. A storage unit according to claim 3, wherein at least one cluster of stacks is a rotatable carousel of two or more stacks, and wherein each carousel is rotatable around an individual carousel axis that is parallel to said vertical axis and arranged to allow different stacks of a carousel to reach the radial access position upon rotation of said carousel around said carousel axis.

5. A storage unit according to claim 1, comprising at least two, such as at least three, such as at least five, clusters of two or more stacks in each cluster.

6. A storage unit according to claim 1, wherein each cluster comprises at least three, such as at least five, stacks having vertically stacked storage locations.

7. A storage unit according to claim 1, wherein the stacks of at least one cluster are arranged in a moveable loop such that a movement of the stacks in the loop allows said first collector arm to engage storage locations of different stacks in said moveable loop.

8. A storage unit according to claim 1, wherein at least one cluster comprises X number of static stack positions occupied by less or equal to X−1 stacks, and wherein a rearrangement of said X−1 stacks in said stack positions allows said first collector arm to engage storage locations of different stacks in said cluster.

9. A storage unit according to claim 1, wherein the clusters are moveably arranged in relation to said first collector arm.

10. A storage unit according to claim 9, wherein the clusters are arranged onto individual vehicles capable of moving freely in relation to said first collector arm.

11. A storage unit according to claim 1, wherein the SMT supplies are stored in component reels, and said reels are arranged in the vertically stacked storage locations of said stacks.

12. A storage unit according to claim 1, further comprising a second terminal for inserting and receiving SMT supplies to and from the unit, and a second collector arm arranged for transporting SMT supplies between storage locations and said second terminal, said second collector arm being moveably arranged in the vertical direction along said stacks so as to enable engagement with the vertically stacked storage locations of a stack.

13. A storage unit according to claim 12, wherein the clusters of stacks are arranged into at least a first group of clusters, which is arranged for allowing engagement with only the first collector arm, at least one shared cluster, which is arranged for allowing different stacks of the shared cluster to engage with both collector arms simultaneously, and at least a second group of clusters, which is arranged for allowing engagement with only the second collector arm.

14. A storage unit according to claim 13, wherein the stacks of at least one shared cluster are arranged in a moveable loop such that a movement of the stacks in the loop allows said collector arms to engage storage locations of different stacks in said moveable loop.

15. A storage unit according to claim 1, wherein the SMT supplies comprises electronic and/or electrical components.

16. A method for operating a storage unit for SMT supplies according to claim 1, comprising the steps of
a1) receiving a first input data representing a first target location of a target stack for the collector arm;
b1) moving at least one stack of a cluster to enable engagement with the vertically stacked storage locations of the target stack by said collector arm;
c1) moving said collector arm from the terminal into engagement with said first target location of said target stack and collecting or storing a component of the SMT supplies at said first target location; and
d1) moving the collector arm back to the terminal.

17. A method according to claim 16, further comprising the steps of
a2) receiving a second input data representing a second target location of a target stack for the collector arm;
b2) moving at least one stack of a cluster to enable engagement with the vertically stacked storage locations of the target stack by said collector arm;
c2) moving said collector arm from the terminal into engagement with said second target location of said target stack and collecting or storing a component of the SMT supplies at said second target location; and
d2) moving the collector arm back to the terminal;
wherein at least one of steps a2) and b2) are performed simultaneously as any one of steps c1) or d1).
